(19) United States
(12) Patent Application Publication
(10) Pub. No.: US 2016/0233234 A1
(43) Pub. Date: Aug. 11, 2016

(54) ARRAY SUBSTRATE AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Ming YANG, Beijing (CN); Xi CHEN, Beijing (CN); Xue DONG, Beijing (CN)

(73) Assignees: BEIJING BOE OPTOELECTRONICS TECHNOLOGY CO., LTD., Beijing (CN); BOE TECHNOLOGY GROUP CO., LTD., Beijing (CN)

(21) Appl. No.: 14/753,258

(22) Filed: Jun. 29, 2015

(30) Foreign Application Priority Data
Feb. 5, 2015 (CN) 201510061687.4

(51) Int. Cl. H01L 27/12

(52) U.S. Cl. CPC H01L 27/124

(57) ABSTRACT

The present disclosure provides an array substrate and a display device. The array substrate includes a plurality of data lines, a plurality of gate lines and a plurality of sub-pixel units defined by the plurality of data lines and the plurality of gate lines crossed with the plurality of data lines. Each gate line is connected with a row of sub-pixel units in an extension direction of the gate line. Each data line is connected with sub-pixel units which are arranged alternately at different sides of the each data line. Sub-pixel units connected with a same data line have an identical color

### CROSS-REFERENCE TO RELATED APPLICATION

This application claims priority to Chinese Patent Application No. 201510061687.4 filed on Feb. 5, 2015, the disclosures of which are incorporated in their entirety by reference herein.

### TECHNICAL FIELD

The present disclosure relates to the field of display technology, in particular to an array substrate and a display device.

### BACKGROUND

Recently, a market share of smart phones with high resolution and large screens is gradually increased. On the one hand, with resolution of smart phone products being higher, a pixel size is increasingly fine, which poses much difficulty for panel makers in manufacturing processes. However, for virtual display products, by reducing data lines in display devices in addition to using algorithms or applying signal processing, the display effect thereof can be close to the real resolution products, thus greatly improving the panel makers' ability of manufacturing processes. On the other hand, for the mobile phones with large screens, at the same time of bring viewing comfort, a short standby time has gradually become the obstacle to their development. Besides gradually enhancing the capacity of the battery, it has increasingly become an important development direction of the intelligent mobile phone to seek a scheme to reduce the power consumption. For panel makers, it is a common method to choose an optimized driving circuit to reduce the power consumption of the screen. For example, for a Z inversion type liquid crystal panel, a dot inversion display effect can be achieved by using a polarity reversal method i.e., a column inversion, which can greatly reduce power consumption. However, when displaying a pure color picture (one of R, G, B), two thirds of data lines should be driven by pulse waveform, which makes large power consumption.

### SUMMARY

The technical problem to be solved by the present disclosure is how to reduce the power consumption in a Z inversion type liquid crystal panel.

In order to solve the above technical problems, one aspect of the present disclosure provides an array substrate, including a plurality of data lines, a plurality of gate lines and a plurality of sub-pixel units defined by the plurality of data lines and the plurality of gate lines crossed with the plurality of data lines. Each gate line is connected with a row of sub-pixel units in an extension direction of the each gate line. Each data line is connected with sub-pixel units which are alternately arranged at different sides of the each data line; sub-pixel units connected with each single data line have an identical color.

Alternatively, sub-pixel units in each row and sub-pixel units in a row adjacent to the each row are arranged to be staggered to each other; each sub-pixel unit has a color different from a color of each adjacent sub-pixel.

Alternatively, a distance from a geometry center of each sub-pixel unit to a geometry center of every sub-pixel unit adjacent to the each sub-pixel unit in a column direction is identical; the column direction is a direction perpendicular to the plurality of gate lines.

Alternatively, sub-pixel units in each row and sub-pixel units in a row adjacent to the each row are arranged to be staggered by ½ width of one sub-pixel unit.

Alternatively, among sub-pixel units in every two adjacent rows, every three sub-pixel units which are adjacent to each other have different colors, are arranged as a triangle and define a pixel unit.

Alternatively, a shape of each sub-pixel unit is rectangle.

Alternatively, a width to length ratio of each sub-pixel unit is in a range of 1:3˜1:1.

Alternatively, the plurality of sub-pixel units includes sub-pixel units having a first color, sub-pixel units having a second color and sub-pixel units having a third color; the sub-pixel units having the first color, the sub-pixel units having the second color and the sub-pixel units having the third color are arranged periodically in each row.

Alternatively, the first color is red, the second color is green, and the third color is blue.

In order to solve the above technical problem, the present disclosure further provides a display device, including the above array substrate.

In order to solve the above technical problems, the present disclosure further provides an array substrate, including a plurality of data lines, a plurality of gate lines and a plurality of sub-pixel units defined by crossing the plurality of data lines and the plurality of gate lines; wherein each gate line is connected with a row of sub-pixel units in an extension direction of the each gate line; each data line is connected with two sub-pixel units having a same color among the sub-pixel units in every two adjacent rows.

Alternatively, sub-pixel units connected with each single data line form two columns of sub-pixel units having the same color at two sides of the each single data line; a column direction of the two columns of sub-pixel units having the same color is perpendicular to an extension direction of the gate lines.

In the array substrate according to the present disclosure, sub-pixel units connected with a same data line have an identical color. When displaying a pure color picture, signals in all the data lines are direct current signals, thereby significantly reducing the power consumption; and when displaying a certain gray scale, a charging time for pixels is increased, thereby reducing the risk of undercharge.

### BRIEF DESCRIPTION OF THE DRAWINGS

FIG. 1 is a schematic diagram showing an array substrate according to one embodiment of the present disclosure;

FIG. 2 is a schematic diagram showing an array substrate according to another embodiment of the present disclosure;

FIG. 3 is a schematic diagram showing arrangements of sub-pixel units in an array substrate according to one embodiment of the present disclosure;

FIG. 4 is a schematic diagram showing a charging state for each sub-pixel unit when the array substrate shown in FIG. 2 displays a pure color picture;

FIG. 5 is a schematic diagram showing a waveform of each data line when the array substrate shown in FIG. 2 displays a pure color picture;

FIG. 6 is a schematic diagram showing a charging state for each sub-pixel unit of an array substrate of which each single data line is connected with sub-pixel units of two colors when displaying a pure color picture;

FIG. 7 is a schematic diagram showing a waveform of each data line when the array substrate shown in FIG. 6 displays a pure color picture;

FIG. 8 is a schematic diagram showing a charging state for each sub-pixel unit when the array substrate shown in FIG. 2 displays a mixed color picture;

FIG. 9 is a schematic diagram showing a waveform of each data line when the array substrate shown in FIG. 2 displays a mixed color picture;

FIG. 10 is a schematic diagram showing a charging state for each sub-pixel unit when the array substrate shown in FIG. 6 displays a mixed color picture; and

FIG. 11 is a schematic diagram showing a waveform of each data line when the array substrate shown in FIG. 6 displays a mixed color picture.

### DETAILED DESCRIPTION

Embodiments of the present disclosure will be further described below in conjunction with the accompanying drawings and examples. The following embodiments are merely used to illustrate the present disclosure, but not intended to limit the scope of the present disclosure.

One embodiment of the present disclosure provides an array substrate. The array substrate includes a plurality of data lines, a plurality of gate lines and a plurality of sub-pixel units defined by crossing the plurality of data lines and the plurality of gate lines. Each gate line is connected with a row of sub-pixel units in an extension direction of the gate line. Each data line is connected with sub-pixel units which are alternately arranged at different sides of the data line (that is, the array substrate is a Z inversion type array substrate). In the array substrate, sub-pixel units connected with each single same data line have an identical color.

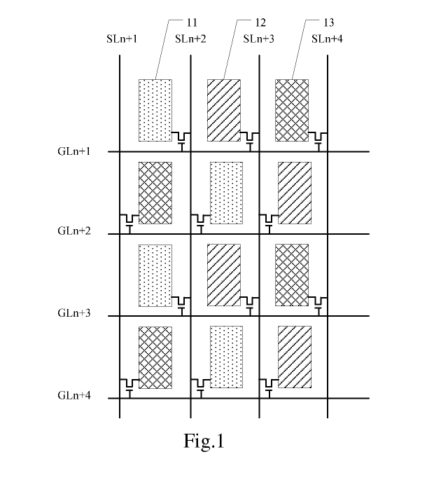

Referring to FIG. 1, which is a schematic diagram showing an array substrate according to one embodiment of the present disclosure, the array substrate includes a plurality of data lines ( . . . SLn+1, SLn+2, SLn+3, SLn+4, . . . ), a plurality of gate lines ( . . . GLn+1, GLn+2, GLn+3, GLn+4, . . . ) and a plurality of sub-pixel units which are defined by crossing the data lines and the gate lines and arranged in an array. The array substrate is a Z inversion type array substrate. Each gate line is connected with a row of sub-pixel units in an extension direction of the gate line. Each data line is connected with sub-pixel units which are alternately arranged at different sides of the each data line.

The array substrate includes sub-pixel units of three colors, which are sub-pixel units 11 having a first color, sub-pixel units 12 having a second color and sub-pixel units 13 having a third color, respectively. The sub-pixel units having the first color, the sub-pixel units having the second color and the sub-pixel units having the third color are arranged periodically in each row. The first color, the second color, and the third color may be one of red (R), green (G) and blue (B), respectively. For example, the first color may be red (R), the second color may be green (G), and the third color may be blue (B). In the array substrate, sub-pixel units connected with each single data line have identical color. For example, the data line SLn+2 is connected with the sub-pixel units 11 having the first color, the data line SLn+3 is connected with the sub-pixel units 12 having the second color and the data line SLn+4 is connected with the sub-pixel units 13 having the third color.

In the Z inversion type array substrate according to one embodiment of the present disclosure, the sub-pixel units connected with each single data line have identical color, therefore, when displaying a pure color picture, signals in all the data lines are direct current (DC) signals, which significantly reduces the power consumption; and when displaying a certain gray scale (that is, R(Lm), G(Ln), B(Lp), where m, n, p are any integers between 0˜255), the pixel charging time is increased, thereby reducing the risk of undercharge.

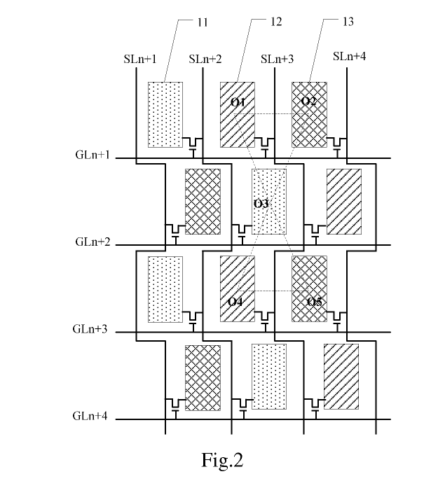

Referring to FIG. 2, which is a schematic diagram showing an array substrate according to another embodiment of the present disclosure, the array substrate includes a plurality of data lines ( . . . SLn+1, SLn+2, SLn+3, SLn+4, . . . ), a plurality of gate lines ( . . . GLn+1, GLn+2, GLn+3, GLn+4, . . . ) and a plurality of sub-pixel units which are defined by crossing the plurality of data lines and the plurality of gate lines. The array substrate is a Z inversion type array substrate. Each gate line is connected with a row of sub-pixel units in an extension direction of the gate line. Each data line is connected with sub-pixel units which are alternately arranged at different sides of the each data line. The array substrate includes sub-pixel units of three colors, which are sub-pixel units 11 having a first color, sub-pixel units 12 having a second color and sub-pixel units 13 having a third color, respectively. The sub-pixel units 11 having the first color, the sub-pixel units 12 having the second color and the sub-pixel units 13 having the third color are arranged periodically in each row. The sub-pixel units connected with each single data line have an identical color.

In addition, in the array substrate, sub-pixel units in each row and sub-pixel units in a row adjacent to the each row are arranged to be staggered to each other. Each sub-pixel unit has a color different from a color of each adjacent sub-pixel unit. That is, three adjacent sub-pixel units in two adjacent rows are arranged as a triangle, which can form a pixel unit. By the above arrangement, degrees of dispersion of each kind of sub-pixel units can be increased. Therefore, when the array substrate is used in a virtual display, the various colors are distributed more uniformly over the virtual space.

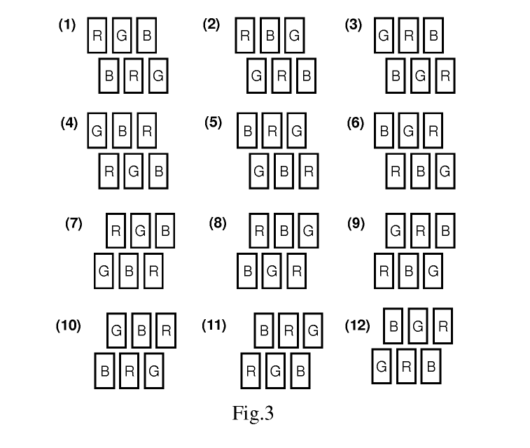

For example, when the array substrate is an RGB mode array substrate, that is, the first color, the second color and the third color are one of red (R), green (G), blue (B), respectively, the arrangement of the sub-pixel units can employ any of arrangements (1)˜(12) as shown in FIG. 3.

Alternatively, in order to further improve the uniformity of color displaying of the array substrate, a shape and size of each sub-pixel unit is identical, and a distance from a geometry center of each sub-pixel unit to a geometry center of each adjacent sub-pixel unit in a column direction is identical. The column direction is a direction perpendicular to the plurality of gate lines. That is to say, for each sub-pixel unit, any two sub-pixel units which are adjacent to the each sub-pixel unit in the column direction can be arranged symmetrically relative to the each sub-pixel unit. For example, as shown in FIG. 2, for the sub-pixel unit with a geometry center O3, the sub-pixel units which are adjacent to the sub-pixel unit with the geometry center O3 in the vertical direction include two sub-pixel units in an upper row with geometry centers O1 and O2, respectively, and two sub-pixel units in a lower row with geometry centers O4 and O5, respectively. In order to improve the uniformity of color displaying of the array substrate, a distance from O3 to O1, a distance from O3 to O2, a distance from O3 to O4 and a distance from O3 to O5 may be identical. Specifically, the sub-pixel units in two adjacent rows may be arranged to be staggered by ½ width of one sub-pixel unit.

The array substrate provided in the present disclosure can be used in a virtual display. A shape of each sub-pixel unit may be a rectangle having a width to length ratio in a range of 1:3˜1:1 for example, 1:2, 1:1.5. For example, a pixel unit in a typical structure includes three sub-pixel units each having a width of a and a length of 3a. In order to reduce the number of data lines in the array substrate, the sub-pixel units in the present disclosure can have a width of 2a and a length of 3a, so that a physical space area of three sub-pixel units according to the present disclosure is equal to a physical space area of two typical pixel units. Or, the sub-pixel units in the present disclosure can have a width of 1.5a and a length of 3a, so that a physical space area of two sub-pixel units according to the present disclosure is equal to a physical space area of one typical pixel unit. Or, the sub-pixel units in the present disclosure can have a width of 3a and a length of 3a, so that a physical space area of one sub-pixel unit according to the present disclosure is equal to a physical space area of one typical pixel unit.

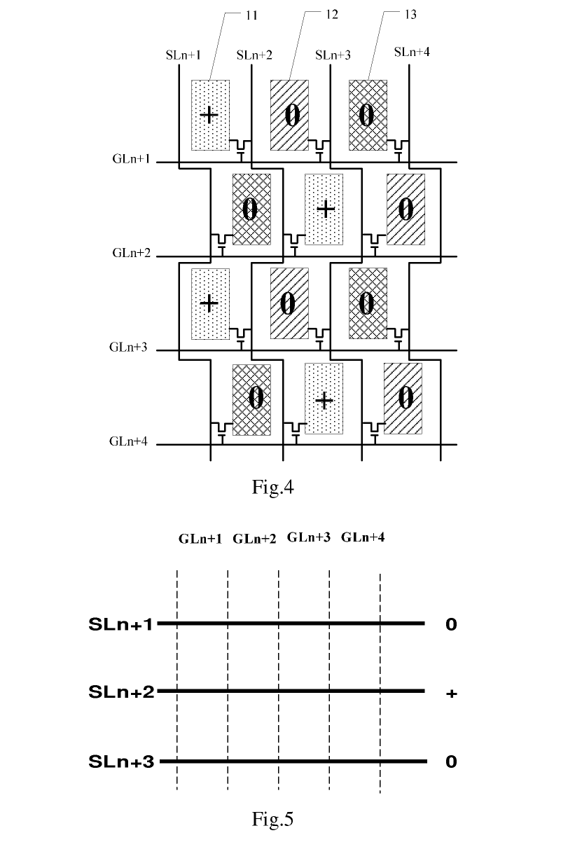

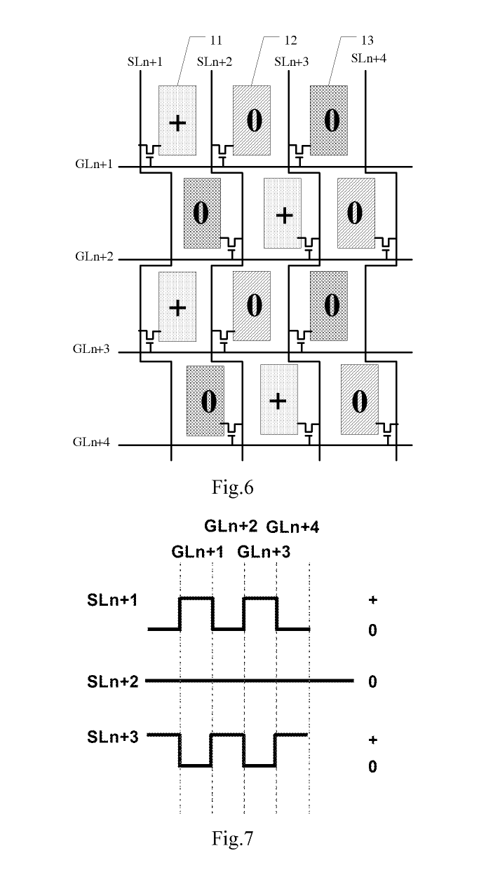

Specifically, for the array substrate shown in FIG. 2, when displaying a pure color picture of the first color, a charging state for each sub-pixel unit in the array substrate is shown in FIG. 4, and a signal waveform for each data line is shown in FIG. 5, and the signal waveform for each data line is a DC waveform. For an array substrate of which each single data line is connected with sub-pixel units of two colors, as shown in FIG. 6, when displaying a pure color picture of the first color, a signal waveform for each data line is shown in FIG. 7. It can be seen from FIG. 7 that, except for the signal waveform for SLn+2 is a DC waveform (a voltage is zero, i.e., equal to a common electrode voltage), both the signal waveforms for SLn+1 and SLn+3 are alternating current (AC) waveforms. Therefore, compared to a manner in which each single data line is connected with sub-pixel units of two colors, a manner in which each single data line is connected with sub-pixel units of an identical color according to the present disclosure can significantly reduce the power consumption.

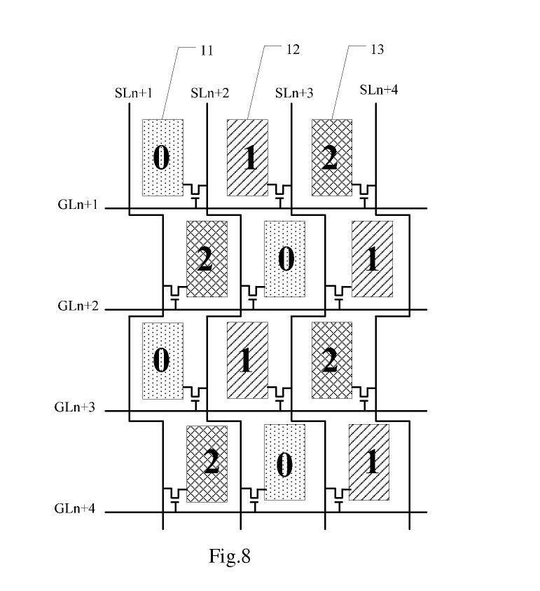

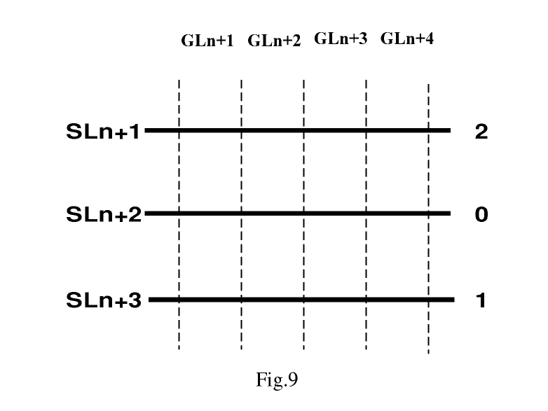

In addition, when the first color is red (R), the second color is green (G), and the third color is blue (B), and when the array substrate shown in FIG. 2 displays a mixed color picture of R0G127L255, a charging state for each sub-pixel unit in the array substrate is shown in FIG. 8, and a signal waveform for each data line is shown in FIG. 9, the signal waveform for each data line is a DC waveform.

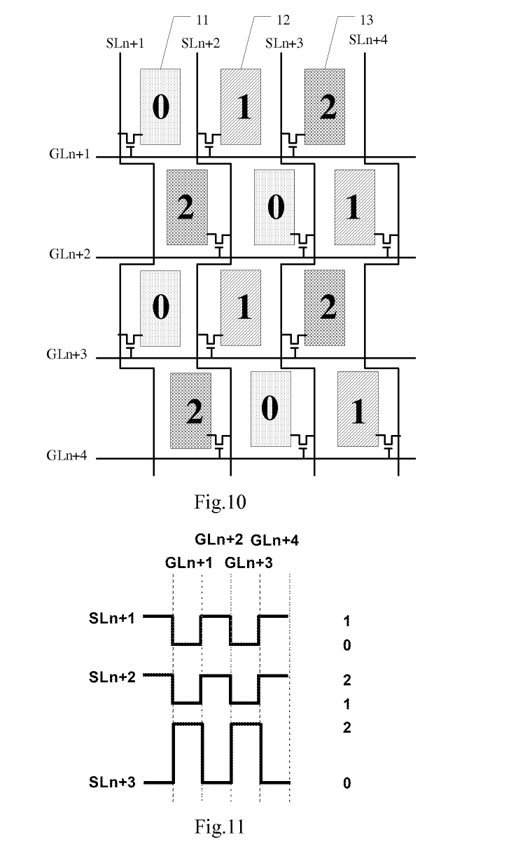

While for a structure as shown in FIG. 6, when displaying a mixed color picture of R0G127L255, a charging state for each sub-pixel unit in the array substrate is shown in FIG. 10. Voltages of sub-pixel units which are of different rows but connected with a same data line are different. A signal waveform for each data line is shown in FIG. 11. It can be seen from FIG. 11 that, signals for all the data lines are AC signals, which causes large power consumption. Meanwhile, there is a risk of undercharge for sub-pixel units in each row. Taking SLn+3 as an example, a voltage at the data line is fluctuated between a high level (2) and a common electrode voltage (0). Due to the existence of a load, a signal outputted by a data integrated circuit (IC) has some delay. Therefore, when the signal for the data line is changed between high and low levels, there always is a time delay. Specially, when there is a large difference between the high and low levels, the signal delay is correspondingly large. As a result, a charge time of the pixels becomes shorter correspondingly, thereby causing the risk of undercharge. However, for the structure in FIG. 2 according to the present disclosure, since all the data line signals are DC signals, the power consumption is small; meanwhile, there is no needs to change between high and low levels for data lines of adjacent rows, a charge time of the pixels becomes longer correspondingly, thereby significantly reducing the risk of undercharge

Furthermore, the present disclosure provides a display device, including the above array substrate. The display device according to one embodiment of the present disclosure may be a laptop display screen, a liquid crystal display device, a liquid crystal TV, a digital photo frame, a mobile phone, a tablet PC and any other products or components with display functions.

The above embodiments are merely intend to illustrate the present disclosure and shall not be used to limit the scope of the present disclosure. It should be noted that, a person skilled in the art may make improvements and modifications without departing from the principle of the present disclosure. Therefore, all the equivalent technical schemes shall fall within the scope of the present disclosure. The protection scope of the present disclosure shall be defined by the claims.

What is claimed is:

1. An array substrate, comprising a plurality of data lines, a plurality of gate lines and a plurality of sub-pixel units defined by the plurality of data lines and the plurality of gate lines crossed with the plurality of data lines; wherein each gate line is connected with a row of sub-pixel units in an extension direction of the each gate line; each data line is connected with the sub-pixel units which are alternately arranged at different sides of the each data line; and the sub-pixel units connected with each single data line have an identical color.

2. The array substrate according to claim 1, wherein the sub-pixel units in each row and the sub-pixel units in a row adjacent to the each row are arranged in a staggered manner; and each sub-pixel unit has a color different from each adjacent sub-pixel.

3. The array substrate according to claim 2, wherein a distance from a geometry center of each sub-pixel unit to a geometry center of every sub-pixel unit adjacent to the each sub-pixel unit in a column direction is identical; and the column direction is a direction perpendicular to the plurality of gate lines.

4. The array substrate according to claim 2, wherein the sub-pixel units in each row and the sub-pixel units in a row adjacent to the each row are staggered by ½ width of one sub-pixel unit.

5. The array substrate according to claim 2, wherein among sub-pixel units in every two adjacent rows, every three sub-pixel units which are adjacent to each other have different colors, are arranged as a triangle and define a pixel unit.

6. The array substrate according to claim 1, wherein a shape of each sub-pixel unit is a rectangle.

7. The array substrate according to claim 6, wherein a width to length ratio of each sub-pixel unit is in a range of 1:3˜1:1.

8. The array substrate according to claim 1, wherein the plurality of sub-pixel units comprises sub-pixel units having a first color, sub-pixel units having a second color and sub-pixel units having a third color; and the sub-pixel units having the first color, the sub-pixel units having the second color and the sub-pixel units having the third color are arranged periodically in each row.

9. The array substrate according to claim 8, wherein the first color is red, the second color is green, and the third color is blue.

10. A display device, comprising the array substrate according to claim 1.

11. An array substrate, comprising a plurality of data lines, a plurality of gate lines and a plurality of sub-pixel units defined by the plurality of data lines and the plurality of gate lines crossed with the plurality of data lines;
wherein each gate line is connected with a row of sub-pixel units in an extension direction of the each gate line; and
each data line is connected with two sub-pixel units having a same color among the sub-pixel units in every two adjacent rows.

12. The array substrate according to claim 11, wherein the sub-pixel units connected with each single data line form two columns of sub-pixel units having the same color at two sides of the each single data line; and a column direction of the two columns of sub-pixel units having the same color is perpendicular to the extension direction of the gate lines.

13. The array substrate according to claim 11, wherein the sub-pixel units in each row and the sub-pixel units in a row adjacent to the each row are arranged in a staggered manner; and each sub-pixel unit has a color different from each adjacent sub-pixel unit.

14. The array substrate according to claim 13, wherein a distance from a geometry center of each sub-pixel unit to a geometry center of every sub-pixel unit adjacent to the each sub-pixel unit in a column direction is identical; and the column direction is a direction perpendicular to the plurality of gate lines.

15. The array substrate according to claim 13, wherein the sub-pixel units in each row and the sub-pixel units in a row adjacent to the each row are staggered by ½ width of one sub-pixel unit.

16. The array substrate according to claim 13, wherein among the sub-pixel units in every two adjacent rows, every three sub-pixel units which are adjacent to each other have different colors, are arranged as a triangle and define a pixel unit.
